(19) United States
(12) Patent Application Publication
(10) Pub. No.: US 2010/0140812 A1
(43) Pub. Date: Jun. 10, 2010

(54) SEMICONDUCTOR DEVICE

(75) Inventor: Seiya FUJII, Tokyo (JP)

Correspondence Address: YOUNG & THOMPSON, 209 Madison Street, Suite 500, Alexandria, VA, 22314, US

(73) Assignee: ELPIDA MEMORY, INC., Tokyo (JP)

(21) Appl. No.: 12/631,481

(22) Filed: Dec. 4, 2009

(30) Foreign Application Priority Data
Dec. 4, 2008 (JP) 2008-309645

(51) Int. Cl. H01L 23/498

(52) U.S. Cl. 257/778; 257/E23.06

(57) ABSTRACT

Semiconductor device 1 according to the present invention includes wiring board 8 having mounting surface 8a mounted with laminated semiconductor chips 2 and plural semiconductor chips 2 mounted on mounting surface 8a of wiring board 8. Plural semiconductor chips 2 mounted on mounting surface 8a of wiring board 8 include second semiconductor chips 2b with circuit formation surfaces 3 directed to the mounting surface 8a side of wiring board 8 and first semiconductor chips 2a with circuit formation surfaces 3 directed to the opposite side of the mounting surface 8a side of wiring board 8.

This application is based upon and claims the benefit of priority from Japanese patent application No. 2008-309645, filed on Dec. 4, 2008, the disclosure of which is incorporated herein in its entirety by reference.

### BACKGROUND OF THE INVENTION

1. Field of the Invention

The present invention relates to a semiconductor device having a structure in which plural semiconductor chips including through electrodes are laminated.

2. Description of Related Art

In recent years, due to an increase of functions and an increase in the speed of semiconductor chips, high-density packaging by laminating semiconductor chips in a package is required of a semiconductor device. However, in a laminated type semiconductor device in the past, since electrode pads of semiconductor chips and connection pads of a wiring board are connected by wire bonding, long wires prevent an increase in speed and a reduction in the thickness of the semiconductor device.

As a method of solving this problem, there is proposed a technique for forming through electrodes in semiconductor chips and laminating the semiconductor chips through a flip-chip junction method (e.g., Japanese Patent Laid-Open No. 2004-281980).

FIG. 1 is a schematic side sectional view of an example of a semiconductor device having structure in which semiconductor chips are laminated by such a flip-chip junction method. FIG. 2 is a plan view along line A-A′ in FIG. 1.

Semiconductor device 100 includes wiring board 108, semiconductor chips 102, resin 101, and through electrodes 104.

Connection pads 107 are formed on one principal plane of wiring board 108. Bumps for secondary packaging 109 are formed on the other principal plane on the opposite side of the one principal plane.

Plural semiconductor chips 102 having through electrodes 104 are laminated on mounting surface 108a of wiring board 108. Circuit surfaces 103 are formed on one surface of semiconductor chips 102. Semiconductor chip 102 in the bottom layer is flip-chip packaged on wiring board 108 with through electrode 104 of semiconductor chip 102 and connection pads 107 of wiring board 108 connected by bumps 106. Semiconductor chip 102 in the bottom layer is laminated on mounting surface 108a with circuit surface 103 directed upward.

Semiconductor chip 102 is further flip-chip packaged on semiconductor chip 102 in the bottom layer. Semiconductor chip 102 laminated on semiconductor chip 102 in the bottom layer is also laminated with circuit surface 103 directed upward. Specifically, the circuit surface 103 side of through electrode 104 of semiconductor chip 102 in the bottom layer and the opposite side of the circuit surface 103 side of through electrode 104 of semiconductor chip 102 above semiconductor chip 102 in the bottom layer are connected by bumps 106. Laminated semiconductor chips 102 are flip-chip joined to each other in the same manner. In other words, in all semiconductor chips 102 laminated on mounting surface 108a of wiring board 108, circuit surfaces 103 face up.

Under-fill 105 is filled in a gap between wiring board 108 and semiconductor chip 102 and gaps among respective semiconductor chips 102. Under-fill 105 covers both the principal planes and the sides of semiconductor chips 102.

Resin 101 is also formed on wiring board 108. Resin 101 covers laminated plural semiconductor chips 102 via under-fill 105. Resin 101 is formed of, for example, epoxy resin.

A semiconductor chip mounted on a wiring board is formed to be thin in order to meet the requirement for thin-packaging. For example, the rear surface of the semiconductor chip is ground to a thickness of about 30 μm to 70 μm. However, the semiconductor chip more easily warps because the semiconductor chip is thinner. For example, before semiconductor chips are cut out from a wafer, the wafer may curl up like a scroll.

When plural semiconductor chips that easily warp are laminated, warping forces of the respective semiconductor chips are accumulated and the warping force of all the laminated semiconductor chips is large. In particular, when the same semiconductor chips are laminated in the same direction, as in a memory, all the semiconductor chips warp in the same direction by the same amount. Therefore, as the number of laminations of semiconductor chips is increased more, the warping force of all the laminated semiconductor chips increases. As a result, in some cases, a problem occurs in that, for example, the semiconductor chips peel off from a wiring board having a shape that is different from the shape of the warp of the laminated semiconductor chips and a bump rupture failure occurs.

It is necessary to compress the semiconductor chips in order to suppress the warp of the semiconductor chips. However, in some case, the semiconductor chips are cracked by the compressing operation.

### SUMMARY

The present invention seeks to solve one or more of the above problems, or to improve upon those problems at least in part.

A semiconductor device according to an embodiment of the present invention includes: a wiring board having a mounting surface on which laminated semiconductor chips are mounted; and a plurality of the semiconductor chips mounted on the mounting surface of the wiring board, wherein the plurality of the semiconductor chips mounted on the mounting surface of the wiring board include first semiconductor chips with circuit formation surfaces, on which circuits are formed, directed to an opposite side of the mounting surface side of the wiring board and second semiconductor chips with the circuit formation surfaces directed to the mounting surface side of the wiring board.

In the semiconductor device according to the embodiment of the present invention, the first semiconductor chips mounted with the circuit formation surfaces thereof directed to the opposite side of the mounting surface side of the wiring board and the second semiconductor chips mounted with the circuit formation surfaces thereof directed to the opposite side of the mounting surface side are laminated. Therefore, the warping force generated in the first semiconductor chips and the warping force generated in the second semiconductor chips cancel each other out. Consequently, a warp due to lamination of thinned semiconductor chips can be suppressed. It is possible to prevent the rupture of bumps between the semiconductor chip and the wiring board. In the semiconductor device according to the embodiment of the present invention, the semiconductor chips are laminated on the wiring board in a flat state while the semiconductor chips cancel out the warpage of each other. Therefore, it is possible to prevent a fall in yield of bumps due to coplanarity (a flatness failure). Further, in the semiconductor device according to the embodiment of the present invention, compressing on the semiconductor chips performed in the past to suppress a warp of the semiconductor chips can be reduced. Consequently, it is possible to suppress a crack failure of the semiconductor chips due to the compressing operation.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a schematic side sectional view of an example of a semiconductor device in the past;

FIG. 2 is a plan view along line A-A′ in FIG. 1;

FIG. 3 is a schematic side sectional view of a semiconductor device according to an embodiment of the present invention;

FIG. 4 is a plan view along line A-A′ in FIG. 3;

FIG. 5A is a diagram for explaining warping force F generated in a semiconductor chip in a state before being laminated;

FIG. 5B is a diagram for explaining warping force F generated in a semiconductor chip in a state before being laminated; and

FIG. 6 is a diagram for explaining a state in which warping forces F are cancelled by a method of laminating semiconductor chips according to the embodiment of the present invention.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

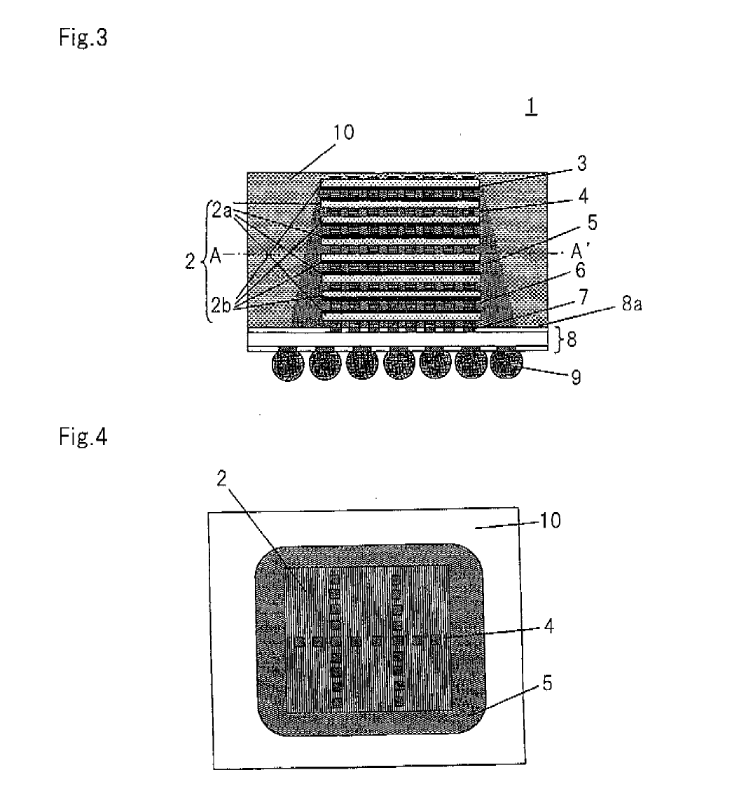

FIG. 3 is a schematic side sectional view of a semiconductor device according to a first embodiment of the present invention. FIG. 4 is a plan view along line A-A′ in FIG. 3.

Plural semiconductor chips 2 are laminated on mounting surface 8a of wiring board 8 of semiconductor device 1. Plural semiconductor chips 2 include plural first semiconductor chips 2a and plural second semiconductor chips 2b.

Connection pads 7 are formed on mounting surface 8a as one principal plane of wiring board 8. Bumps for secondary packaging 9 are formed on a principal plane on the opposite side of mounting surface 8a.

Circuit formation surface 3 is formed on one principal plane in first semiconductor chip 2a. First semiconductor chip 2a has through electrodes 4 piercing from the circuit formation surface 3 side to a surface on the opposite side of circuit formation surface 3. Like first semiconductor chip 2a, circuit formation surface 3 is also formed on one principal plane in second semiconductor chip 2b. Second semiconductor chip 2b also has through electrodes 4 piercing from the circuit formation surface 3 side to a surface on the opposite side of circuit formation surface 3. Positions of through electrodes 4 of reversed second semiconductor chip 2b coincide with positions in non-reversed first semiconductor chip 2a. Therefore, even when first semiconductor chip 2a and reversed second semiconductor chip 2b are connected, the semiconductor chips can function.

First semiconductor chips 2a and second semiconductor chips 2b are alternately laminated on wiring board 8 such that circuit formation surfaces 3 thereof are opposed to each other. In this embodiment, four first semiconductor chips 2a and four second semiconductor chips 2b are alternately laminated. In other words, semiconductor chips 2 are laminated in eight stages in total. In odd number stages, i.e., a first stage, a third stage, a fifth stage, and a seventh stage, counted from the wiring board 8 side, first semiconductor chips 2a are arranged with circuit formation surfaces 3 thereof directed upward. In even number stages, i.e., a second stage, a fourth stage, a sixth stage, and an eighth stage, second semiconductor chips 2b are arranged with circuit formation surfaces 3 thereof directed downward. In other words, semiconductor chips 2 according to this embodiment are laminated such that circuit formation surfaces 3 of first semiconductor chips 2a and circuit formation surfaces 3 of second semiconductor chips 2b are opposed to each other. When semiconductor chips are laminated in this way, the warping forces of thinned semiconductor chips are cancelled. The principle that accounts for cancellation of warping forces will be explained later.

Under-fill 5 is filled in gaps between first semiconductor chips 2a and second semiconductor chips 2b and a gap between first semiconductor chip 2a and wiring board 8. Under-fill 5 is filled in the respective gaps by using the capillarity among the gaps. Under-fill 5 also covers the sides of first semiconductor chip 2a and second semiconductor chip 2b.

Resin 10 is also formed on wiring board 8. Resin 10 covers laminated plural semiconductor chips 2 via under-fill 5. Resin 10 is formed of, for example, epoxy resin or the like.

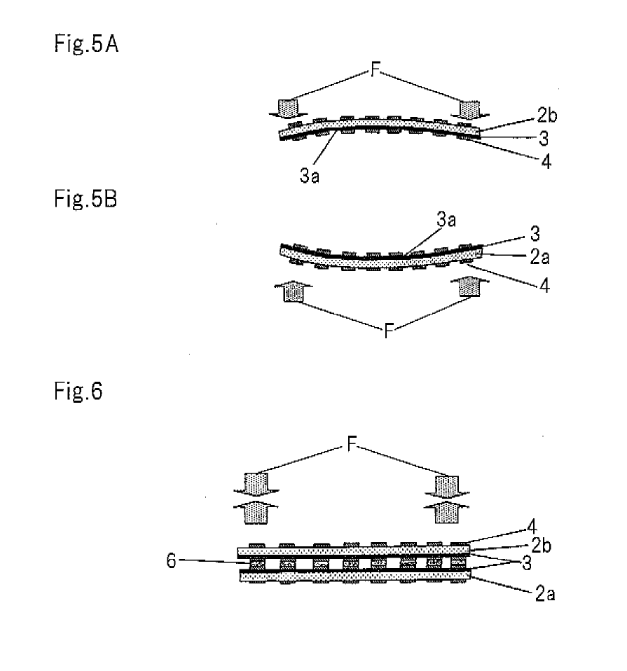

The principle that accounts for cancellation of warping forces of semiconductor chips in this embodiment is explained with reference to FIGS. 5A, 5B, and 6. FIG. 5A is a side view of second semiconductor chip 2b before being laminated. FIG. 5B is a side view of first semiconductor chip 2a before being laminated.

As shown in FIGS. 5A and 5B, as a sectional shape of second semiconductor chip 2b and first semiconductor chip 2a, the sides of circuit formation surface 3 of both the semiconductor chips warp to be concave surfaces 3a before the semiconductor chips are laminated. In this way, usually, semiconductor chip 2 warps to become concave surface 3a on the circuit formation surface 3 side. This is because the coefficient of thermal expansion of SiN or polyimide used for circuit formation surface 3 is larger than the coefficient of thermal expansion of silicon as the main material of a wafer. Specifically, since SiN or polyimide is formed flat in the high-temperature atmosphere, circuit formation surface 3 substantially contracts compared with silicon under the room temperature, and warping force F shown in FIGS. 5A and 5B is generated.

In second semiconductor chip 2b on which circuit formation surface 3 is arranged to be directed downward, as shown in FIG. 5A, since warping force F is generated in the downward direction, concave surface 3a is formed on the lower side. Conversely, in first semiconductor chip 2a on which circuit formation surface 3 is arranged to be directed upward, as shown in FIG. 5B, since warping force F is generated in the upward direction, concave surface 3a is formed on the upper side. In this way, the directions of warping forces F are opposite in second semiconductor chip 2b and first semiconductor chip 2a. Therefore, as shown in FIG. 6, concave surface 3a of second semiconductor chip 2b and concave surface 3a of first semiconductor chip 2a are joined to be opposed to each other out. Consequently, warping force F of second semiconductor chip 2b and warping force F of first semiconductor chip 2a cancel each other.

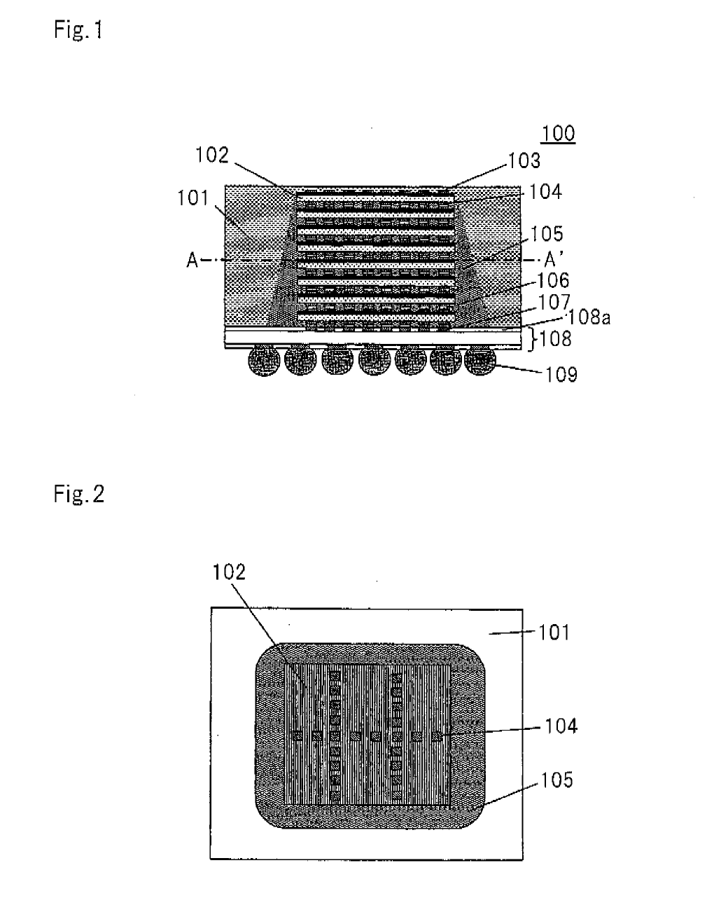

In the example in the past shown in FIG. 1, circuit surfaces 103 of all semiconductor chips 102 are directed upward. When such a laminated structure is adopted, since directions of warping forces F of respective semiconductor chips 102 are the same, warping force F increases according to the number of semiconductor chips. As a result, a rupture failure of bumps 106 occurs between semiconductor chip 102 and wiring board 108 having a shape different from the shape of the warp of semiconductor chip 102.

At the same time, in the case of this embodiment, as explained above, since second semiconductor chips 2b with circuit formation surfaces 3 directed downward and first semiconductor chips 2a with circuit formation surfaces 3 directed upward are alternately laminated, the warping force F of second semiconductor chips 2b and the warping force F of first semiconductor chips 2a cancel each other out. Therefore, warps in all laminated plural semiconductor chips 2 are reduced. Consequently, it is possible to prevent a rupture of bumps 6 between semiconductor chip 2 and wiring board 8.

In the case of this embodiment, since semiconductor chips are laminated on wiring board 8 in a flat state while the semiconductor chips cancel out the warpage of each other, it is possible to prevent a fall in yield of bumps 6 due to coplanarity (a flatness failure).

Further, in the case of this embodiment, compressing on the semiconductor chips performed in the past to suppress a warp of the semiconductor chips can be reduced. Consequently, it is possible to suppress a crack failure of the semiconductor chips due to the compressing.

As explained above, according to this embodiment, since the yield of the semiconductor device in which thinned semiconductor chips 2 are laminated in multiple stages can be improved, a semiconductor device having high density can be stably manufactured at high speed.

In the embodiment explained above, the configuration in which first semiconductor chips 2a and second semiconductor chips 2b are alternately laminated is explained. However, the present invention is not limited to this. Specifically, if semiconductor device 1 has a configuration in which warping forces F of laminated semiconductor chips 2 are cancelled, first semiconductor chips 2a with circuit formation surfaces 3 directed upward and second semiconductor chips 2b with circuit formation surfaces 3 directed downward may be laminated in any combination. For example, two first semiconductor chips 2a may be continuously laminated and two second semiconductor chips 2b may be continuously laminated on two first semiconductor chips 2a. The number of first semiconductor chips 2a and the number of second semiconductor chips 2b are preferably the same. However, the present invention is not limited to this. The number of first semiconductor chips 2a and the number of second semiconductor chips 2b may be different as long as warping forces F of laminated semiconductor chips 2 are cancelled.

The present invention can be applied not only to packaging of semiconductor chips 2 on wiring board 8 but also to packaging of laminated semiconductor chips 2 on other substrates.

It is apparent that the present invention is not limited to the above embodiments, but may be modified and changed without departing from the scope and spirit of the invention.

What is claimed is:

1. A semiconductor device comprising:
a wiring board having a mounting surface on which laminated semiconductor chips are mounted; and
a plurality of the semiconductor chips mounted on the mounting surface of the wiring board, wherein
the plurality of the semiconductor chips mounted on the mounting surface of the wiring board include first semiconductor chips with circuit formation surfaces, on which circuits are formed, directed to an opposite side of the mounting surface side of the wiring board, and second semiconductor chips with the circuit formation surfaces directed to the mounting surface side of the wiring board.

2. The semiconductor device according to claim 1, wherein the first semiconductor chips and the second semiconductor chips are alternately laminated.

3. The semiconductor device according to claim 1, wherein the wiring board and the semiconductor chip are flip-chip joined and the semiconductor chips are also flip-chip joined.

4. The semiconductor device according to claim 2, wherein the wiring board and the semiconductor chip are flip-chip joined and the semiconductor chips are also flip-chip joined.
